(19) United States
(12) Patent Application Publication
(10) Pub. No.: US 2026/0098128 A1
(43) Pub. Date: Apr. 9, 2026

(54) CURABLE BRANCHED ORGANOPOLYSILOXANE, HIGH ENERGY RAY-CURABLE COMPOSITION CONTAINING SAME, AND USE THEREOF

(71) Applicant: DOW TORAY CO., LTD., Shinagawa-Ku, Tokyo (JP)

(72) Inventors: Wenbin LIANG, Ichihara-shi, Chiba (JP); Takuya OGAWA, Ichihara-shi, Chiba (JP)

(21) Appl. No.: 19/114,197

(22) PCT Filed: Sep. 19, 2023
(86) PCT No.: PCT/JP2023/033996

§ 371 Date: Dec. 16, 2025

(30) Foreign Application Priority Data
Sep. 22, 2022 (JP) 2022-151509

(51) Int. Cl. C08G 77/392; C08G 77/00; G03F 7/004; G03F 7/075; G03F 7/20

(52) U.S. Cl. CPC C08G 77/392; C08G 77/70; C08G 77/80; G03F 7/0045; G03F 7/0752; G03F 7/2059

(57) ABSTRACT

[OBJECT] To provide an organopolysiloxane having favorable fine patterning properties (including coatability), a favorable alkali solubility and a favorable high energy beam-curability, and capable of forming a cured film having a high transparency and a practically sufficient mechanical strength when cured, and to provide, along with the use thereof, a high energy beam-curable composition containing the organopolysiloxane. [SOLUTION] Provided are a curable branched organopolysiloxane and a use thereof, wherein the curable branched organopolysiloxane is represented by an average unit formula (1): (R₃SiO_{1/2})ₐ(R₂SiO_{2/2})_{b}(RSiO_{3/2})_{c}(SiO_{4/2})_{d}(O_{1/2}Z)ₑ (1) (wherein R is a group selected from a monovalent hydrocarbon group, an alkoxy group, a hydroxyl group, and a phenolic hydroxyl group-containing group; 0≤a, 0≤b, 0<c, 0≤d, 0≤e, 0.8≤c/(a+b+c+d+e); and the molecule has at least one phenolic hydroxyl group-containing group therein), and wherein the curable branched organopolysiloxane has a weight average molecular weight of 4,000 or less and a polydispersity of 1.3 and less, and preferably has a cage-like molecular structure.

### TECHNICAL FIELD

The present invention relates to an alkali-soluble high energy beam-curable branched organopolysiloxane which can be cured by actinic rays, for example high energy beams or electron beams, and to a high energy beam-curable composition containing the same. The curable branched organopolysiloxane of the present invention has high solubility in aqueous alkali solutions and favorable high energy beam curability, and therefore exhibits excellent lithography performance and is suitable as a resist material or insulating material for electronic and electrical devices that require patterning, and in particular as a material for use as a coating agent.

### BACKGROUND ART

Due to high heat resistance and excellent chemical stability, silicone resins have been used as coating agents, potting agents, insulating materials, and the like for electronic and electrical devices. Among silicone resins, high energy beam-curable silicone compositions have also been reported.

Touch panels are used in various display devices such as mobile devices, industrial equipment, car navigation systems, and the like. In order to improve detection sensitivity, electrical influence from light emitting sites such as light-emitting diodes (LED), organic EL devices (OLED), and the like must be suppressed, and an insulating layer is usually disposed between the light-emitting part and the touchscreen. On the other hand, thin display devices such as OLEDs and the like have a structure in which a plurality of functional thin layers are laminated. In recent years, studies have been conducted to improve the visibility of display devices by laminating insulating layers formed from acrylate polymer with a high refractive index and multifunctional polymerizable monomers, above and below the touchscreen layer. (For example, see Patent Documents 1 and 2)

Advances in photolithography technology have enabled achieving finer patterns in the manufacture of semiconductor elements, and the progress thereof has been remarkable in recent years. Technology for achieving this miniaturization generally involves using light sources with shorter wavelengths, and resist materials using electron beams and extreme ultraviolet (EUV) rays are being investigated for use in regions with a resolution of 20 nm or less. With technology using EUV, excitation of the resist material itself by irradiation is important, and polymers having phenol groups are being actively studied as EUV resist materials. In addition, from the viewpoint of high resolution, particularly uniformity of line width, a compound having a low to moderate molecular weight and a small polydispersity has also attracted attention. Patent Document 3 discloses a resist composition that contains an acrylic polymer having a phenol group and a specific acid generating agent and has favorable stability over time.

Similarly, silicone-based resist materials are also being considered, taking advantage of their excellent etching resistance. Patent Document 4 discloses a resist composition containing a phenol-functional polysiloxane which is a reaction product of a hydrogen-functional polysiloxane, an alkenyl-functional polysiloxane, and a specific diallyl compound. However, since linear polysiloxane components are abundant, the product does not exhibit alkali solubility. Furthermore, Patent Documents 5 and 6 disclose phenol-functional polysilsesquioxanes having a specific structure and resist compositions. These are alkali-soluble, but there are problems with solubility. Similarly, Patent Document 7 discloses a silsesquioxane having both a monovalent organic group having an unsaturated double bond in the molecule and a phenolic hydroxyl group or the like, and also discloses uses thereof. However, problems remain in the alkali solubility (solubility), coatability, and high energy beam curability thereof.

In other words, although phenol-functional polysiloxanes and high energy beam-curable compositions containing these have been disclosed, it is difficult to say that a curable organopolysiloxane in which the polysiloxane itself has a low to moderate molecular weight and a small polydispersity and as well as high solubility in an aqueous alkali solution and exhibits excellent high energy beam curability, and a high energy beam-curable composition containing the same have been sufficiently disclosed.

### PRIOR ART DOCUMENTS

### Patent Documents

Patent Document 1: JP 2013-140229 A
Patent Document 2: JP 2021-61056 A
Patent Document 3: JP 2017-227733 A
Patent Document 4: JP 2004-262952 A
Patent Document 5: JP 2016-212350 A
Patent Document 6: JP 2005-283991 A
Patent Document 7: JP 2020-184010 A

### DISCLOSURE OF INVENTION

### Technical Problem

The present invention has been made to solve the above-mentioned problems. It provides an organopolysiloxane having favorable fine patterning properties (including coatability), a favorable alkali solubility and a favorable high energy beam-curability, and capable of forming a cured film having a high transparency and a practically sufficient mechanical strength when cured, and provides, along with the use thereof, a high energy beam-curable composition containing the organopolysiloxane.

### Solution to Problem

In order to resolve the aforementioned problems, the present invention was achieved based on a discovery: that a curable branched organopolysiloxane having a phenolic hydroxyl group-containing group bonded on a silicon atom in the molecule, including silsesquioxane units (so called T-units) as its principal constituent units, and having a low weight average molecular weight and a small polydispersity has a high solubility in an alkaline aqueous solution; that a high energy beam-curable composition containing the same has an excellent coatability to a substrate and an excellent alkali solubility, exhibits favorable curability; and that a cured product (cured film) thereof has sufficient mechanical strength and favorable transparency. It is preferable that the curable branched organopolysiloxane have a relatively small molecule and a low polydispersity, and it is particularly preferable that from the viewpoint of technical effects, the curable branched organopolysiloxane have a cage-like molecular structure including a perfect cage shape.

The high energy beam-curable composition according to the present invention forms an intermolecular bond and undergoes a curing reaction by irradiation with a high energy beam such as an ultraviolet ray, but any curing means capable of causing a curing reaction may be employed together with the high energy beam or instead of the high energy beam. By way of example, the high energy beam-curable compositions of the present invention may be cured by electron beam irradiation, and such compositions and methods of curing are one of the embodiments of the invention contemplated by and being within the scope of the present invention.

More specifically, the curable branched organopolysiloxane of the present invention is represented by the following average unit formula and has a weight average molecular weight of 4,000 or less, and a polydispersity index (PDI) of 1.3 or less, which are calculated as standard polystyrene and measured by gel permeation chromatography.

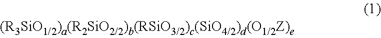

(wherein R is a group selected from an unsubstituted or fluorine-substituted monovalent hydrocarbon group, an alkoxy group, a hydroxyl group and a phenolic hydroxyl group-containing group; a, b, c, d, and e are numbers satisfying the following conditions: 0≤a, 0≤b, 0<c, 0≤d, 0≤e, 0.8≤c/(a+b+c+d+e), and at least one phenolic hydroxyl group-containing group is present in the molecule.)

The curable branched organopolysiloxane may have a weight average molecular weight of 3,500 or less.

In the curable branched organopolysiloxanes, the value of a may be 0, the value of b may be 0, and the value of d may be 0.

In the curable branched organopolysiloxane, the phenolic hydroxyl group-containing group preferably has a structure represented by the following formula (2):

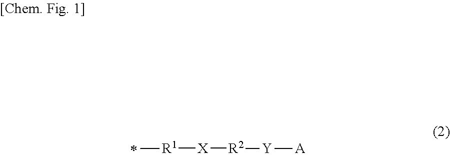

(wherein R¹ is a divalent hydrocarbon group having 2 to 6 carbon atoms; X is an oxygen atom- or sulfur atom-containing divalent linking group; R² is a divalent linking group having 2 or 3 carbon atoms; Y is an oxygen atom or a sulfur atom; the substituent A is a phenolic hydroxyl group represented by the following formula (A1) or a substituted or unsubstituted aromatic hydrocarbon-containing group represented by the following formula (A2), and * is a silicon atom-bonding site on the organopolysiloxane; provided that at least one of As is A1.)

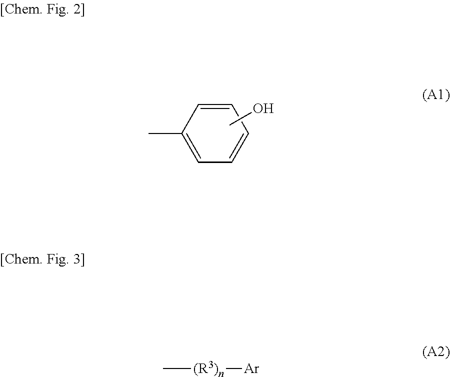

(wherein R³ is an alkylene group having 1 to 3 carbon atoms; n is 0 or 1; and Ar is a monovalent hydrocarbon group or an aromatic hydrocarbon group having 6 to 14 carbon atoms which may be substituted with a halogen group.)

In the curable branched organopolysiloxane, X is at least one divalent linking group selected from an ester group —O(C═O)— and a thioester group —S(C═O)—; and Y may be a sulfur atom.

The curable branched organopolysiloxane preferably has a polydispersity of 1.2 or less and has a cage-like molecular structure.

The curable branched organopolysiloxane may have no more than 12 silicon atoms on average per molecule.

The curable branched organopolysiloxane preferably has on average 4 or more per molecule phenolic hydroxyl group-containing groups.

A coating film containing the curable branched organopolysiloxane preferably has solubility in an aqueous alkali solution with a mass loss rate of 90 mass % or more, when the organopolysiloxane is applied on a glass plate such that the thickness after application is 0.5 μm and the coating film is washed after immersion in a 2.38 mass % aqueous solution of tetramethylammonium hydroxide (TMAH) for 1 minute.

In addition, the present invention provides a high energy beam-curable composition containing at least the following components:
(A) the aforementioned curable branched organopolysiloxane;
(B) a photoacid generating agent in an amount of 0.1 to 20 parts by mass per 100 parts by mass of the component (A);
(C) a crosslinking agent in an amount of 1 to 30 parts by mass per 100 parts by mass of the component (A);
and
(D) an organic solvent.

The high energy beam-curable composition preferably contains a crosslinking agent in an amount of 5 to 30 parts by mass relative to 100 parts by mass of component (A).

The present invention further provides an insulative coating agent containing the high energy beam-curable composition described above. The present invention also provides a resist material containing the high energy beam-curable composition described above.

The present invention further provides a cured product of the high energy beam-curable composition described above. Furthermore, the present invention also provides a method of using the cured product as an insulative coating layer.

The present invention further provides a display device such as a liquid crystal display, organic EL display, or organic EL flexible display that includes a layer containing a cured product of the aforementioned high energy beam-curable composition.

### Effect of the Invention

The curable branched organopolysiloxane of the present invention has a favorable coatability on various substrates. In addition, since the curable branched organopolysiloxane of the present invention has a low molecular weight and a low polydispersity, it exhibits high solubility in an alkaline aqueous solution which is normally used in a development process carried out for forming a pattern having a desired shape.

Therefore, unreacted and uncured organopolysiloxane and curable compositions containing this organopolysiloxane can be easily removed by a washing operation using an alkaline aqueous solution during the development process that accompanies selective high energy beam irradiation, enabling high-precision patterning with a simple process. Furthermore, the curable product formed from the high energy beam-curable composition containing the curable branched organopolysiloxane of the present invention has an advantage of being optically transparent, and being capable of designing the hardness or the like across a wide range. Therefore, the curable composition of the present invention is useful as a resist material that uses a short wavelength light source, particularly EUV. Furthermore, the curable composition of the present invention is also useful as a material for an insulating layer for electronic devices, particularly for thin display devices such as OLEDs, particularly as a patterning material and a coating material.

### DETAILED DESCRIPTION OF THE INVENTION

A configuration of the present invention will be further described in detail below. The curable branched organopolysiloxane of the present invention with a specific structure has a phenolic hydroxyl group-containing group on at least one silicon atom, and has a favorable solubility in an aqueous alkali solution (sometimes referred to as “alkali-solubility” in the present invention), high-precision patterning abilities (including coatability), and high-energy beam curability. The high energy beam-curable composition of the present invention contains, as essential components, (A) the branched organopolysiloxane, (B) a photoacid generating agent, (C) a crosslinking agent, and (D) an organic solvent.

Alkali solubility means that the formed coating film is soluble in the aqueous alkali solution normally used in the development process to form a pattern of a desired shape. Well-known aqueous alkali solutions include basic aqueous solutions of sodium hydroxide (NaOH), potassium hydroxide (KOH), quaternary ammonium salts, and the like, but aqueous solutions of KOH and tetramethylammonium hydroxide (TMAH) are typically used, and TMAH aqueous solutions are particularly widely used. In the present invention, this means that the material is soluble in an aqueous alkali solution.

More specifically, “soluble in an aqueous alkali solution” means that if the branched organopolysiloxane of the present invention is applied to a glass plate to a thickness of 0.5 μm, after which the coating film is immersed in a 2.38% aqueous solution of TMAH for 1 minute and then washed with water, the coating film made of the organopolysiloxane has a mass loss rate of 90 mass % or more. In particular, if the coating film made of the organopolysiloxane has a mass loss rate of 95 mass % or more, or 98 mass % or more when evaluated by the aforementioned method, the coating film can be considered to have particularly excellent solubility in an aqueous alkali solution. Note that spin-coating or other methods are commonly used to apply the organopolysiloxane on a glass plate. If the coating is applied using an organic solvent, as described below, the organic solvent must be removed in advance by drying or other means. Furthermore, if the composition is mainly composed of organopolysiloxane, the solubility of the high energy beam-curable composition containing the organopolysiloxane of the present invention can be evaluated in an aqueous alkali solution by the aforementioned method. Furthermore, the water washing process is generally performed by immersion in a water bath at about room temperature (25° C.) or by running water at about the speed of domestic tap water for 10 to 15 seconds, so as not to adversely affect the formed patterning or the substrate.

Note that since the branched organopolysiloxane of the present invention has a low molecular weight and a small polydispersity, it tends to have an improved solubility in aqueous alkaline solutions and an improved coatability compared to organopolysiloxanes having high molecular weight and containing only silsesquioxane units. As a result, when the solubility in an aqueous alkaline solution of a coating film including the organopolysiloxane is evaluated by the method described above, an organopolysiloxane is obtained that has a particularly excellent alkali solubility where the mass loss rate of the coating film is 98% or more.

The curable branched organopolysiloxane of the present invention is expressed by the following average unit formula (1). (R₃SiO_{1/2})ₐ(R₂SiO_{2/2})_{b}(RSiO_{3/2})_{c}(SiO_{4/2})_{d}(O_{1/2}Z)ₑ (1)
(wherein R is a group selected from an unsubstituted or fluorine-substituted monovalent hydrocarbon group, an alkoxy group, a hydroxyl group and a phenolic hydroxyl group-containing group; a, b, c, d, and e are numbers satisfying the following conditions: 0≤a, 0≤b, 0<c, 0≤d, 0≤e, 0.8≤c/(a+b+c+d+e), and at least one phenolic hydroxyl group-containing group is present in the molecule.)

In the curable branched organopolysiloxane represented by the average unit formula (1), there is a degree of freedom in the ratio of each constituent unit, but the constituent ratio of monoorganosiloxy units (sometimes referred to as T-units or silsesquioxane units) in all siloxane units should satisfy the following formula (3). Considering that the desirable properties of the curable branched organopolysiloxane are a solid with no surface tack and that a low polydispersity is desirable, the monoorganosiloxy unit is the major constituent unit.

$$0.8 \leq c / ( a + b + c + d + e ) \qquad ( 3 )$$

The molecular weight of the curable branched organopolysiloxane of the present invention has a weight average molecular weight of 4,000 or less, which are calculated as standard polystyrene and measured by gel permeation chromatography (GPC). This property makes it easy to design a material that enables an excellent alkali solubility and high precision patterning to be achieved. The value of the weight average molecular weight in the curable branched organopolysiloxane of the present invention is preferably 3,500 or less, more preferably in the range of 500 to 3,500, in the range of 700 to 3,200, or in the range of 1000 to 3,000.

On the other hand, the polydispersity index (hereinafter sometimes referred to as “PDI”) of the curable branched organopolysiloxane is a value defined as a value of “Mw/Mn” using a number average molecular weight (Mn) and a weight average molecular weight (Mw) determined in terms of standard polystyrene by gel permeation chromatography. A smaller PDI value generally means a narrower and sharper molecular weight distribution. Specifically, the polydispersity of the curable branched organopolysiloxane needs to be 1.3 or less, and from the viewpoint of high-precision patterning, particularly reducing nonuniformity of line width in the organopolysiloxane according to the present invention and in the high-energy radiation-curable composition using the organopolysiloxane, the polydispersity is preferably 1.20 or less, and particularly preferably in the range from 1.00 to 1.20.

In the curable branched organopolysiloxane of the present invention, the above-mentioned molecular weight and polydispersity are essential parts of the configuration. When the weight average molecular weight or the polydispersity exceeds the upper limit, one or both of alkali solubility and high-precision patterning properties (including coatability) of the organopolysiloxane according to the present invention and the high energy beam-curable composition using the organopolysiloxane may be impaired, and such a composition cannot be suitably used as a patterning material.

Furthermore, the average number of silicon atoms in the curable branched organopolysiloxane is preferably 12 or less. That is, the branched organopolysiloxanes of the present invention may be branched organopolysiloxanes all of which have the same number of silicon atoms, or may be an optionally combined mixture of branched organopolysiloxanes which have two or more different numbers of silicon atoms. It is preferable, however, that all the molecules of the curable branched organopolysiloxanes should have an average number of silicon atoms of 12 or less. A more preferable average number of silicon atoms is 10 or less, and a still more preferable number is 8 or less. This characteristic also affects the feasibility of high-precision patterning, and it is preferable that the average number of silicon atoms should be small with the deviation thereof being small.

The curable branched organopolysiloxane of the present invention preferably has a cage-like molecular structure. The cage-like molecular structure refers to a so-called polyhedral cluster structure or a structure resembling it, which is also referred to as polyhedral oligomeric silsesquioxane, and has a symmetric molecular structure or a molecular structure resembling it. A regular hexahedron structure having eight silicon atoms, a pentagonal prism structure having ten silicon atoms, and a heptahedron structure having twelve silicon atoms are well known.

In the present invention, in formula (1) a branched organopolysiloxane having a cage-like molecular structure containing, as a major constituent unit, the (RSiO_{3/2})_{c} unit, that is, a silsesquioxane unit, is particularly preferable, wherein a, b, c, d, and e may satisfy the condition of 0.8≤c/(a+b+c+d+e)≤1.0, and it is particularly preferable that a, b, and d should be 0. In addition, as will be described later, e may be 0 and is preferably 0 from the viewpoint of providing a complete cage-like molecular structure. To put it differently, it is particularly preferable that the curable branched organopolysiloxane of the present invention represented by Formula (1) should be a branched organopolysiloxane having a cage-like structure composed only of (RSiO_{3/2})_{c} units, that is, silsesquioxane units. In this case, it goes without saying that the number of c is equal to the number of silicon atoms in the molecule.

In Formula (1), (O_{1/2}Z)ₑ represents a part of the Si—OH groups and/or Si—O-alkyl groups, which remain without completing the condensation reaction when a branched organopolysiloxane is formed that has a cage-like molecular structure which may contain an (R₂SiO_{2/2})_{b} unit and an (SiO_{4/2})ₐ unit wherein the (RSiO_{3/2})_{c} unit is a main constituent unit. To put it differently, each Z independently represents a hydrogen atom or an alkyl group having 1 to 20 carbon atoms, preferably 1 to 6 carbon atoms, more preferably 1 to 3 carbon atoms, and particularly preferably a methyl group, an ethyl group, or an isopropyl group.

When all the condensable reactive groups in the branched organopolysiloxane of formula (1) are bonded to each other to form an Si—O—Si bond, e in formula (1) is 0 (zero). Such a case is called a complete cage-like structure. When e is not 0, all the condensable reactive groups in the branched organopolysiloxane of the formula (1) are not bonded to each other to form a Si—O—Si bond, and a part thereof is SiOZ. Such a case is called a partially cleaved structure. As the cage-like molecular structure of the branched organopolysiloxane, the complete cage-like structure and the partially cleaved structure are known, and either of them can be used as the branched organopolysiloxane represented by the formula (1) of the present invention. However, the branched organopolysiloxane of the formula (1) of the present invention preferably has a complete cage structure (i.e., e=0 in the formula (1)) or a structure resembling it (e.g., e is 15% or less, preferably 10% or less relative to the sum of a+b+c+d). In particular, it is preferable that the branched organopolysiloxane should have a complete cage structure. Specific examples of the complete cage structure and the partial cleavage structure of the branched organopolysiloxane are shown in paragraphs [0047] to [0049] of JP 2010-515778 A, and the cage-like branched organopolysiloxane of the present invention may also have a similar chemical structure.

As will be described later, all of the substituents Rs in the branched polyorganosiloxane of the present invention represented by the average unit formula (1) may be and preferably are phenolic hydroxyl group-containing groups. On the other hand, the other substituents Rs than the phenolic hydroxyl group-containing groups in the average unit formula (1) may be groups selected from unsubstituted or fluorine-substituted monovalent hydrocarbon groups, alkoxy groups, and hydroxyl groups. The unsubstituted or fluorine-substituted monovalent hydrocarbon group preferably has no curing-reactive functional group containing a carbon-carbon double bond or no monovalent organic group having a hetero-atom such as an epoxy group, amino group, sulfide group, or the like. The unsubstituted or fluorine-substituted monovalent hydrocarbon group is preferably a group selected from unsubstituted or fluorine substituted alkyl, cycloalkyl, arylalkyl, and aryl groups with 1 to 20 carbon atoms.

Examples of the alkyl groups above include methyl, ethyl, n-propyl, isopropyl, n-butyl, tert-butyl, sec-butyl, pentyl, hexyl, octyl, and other groups, but methyl groups and hexyl groups are particularly preferable. Examples of the cycloalkyl groups above include cyclopentyl, cyclohexyl, and the like. Examples of the arylalkyl groups above include benzyl, phenylethyl groups, and the like. Examples of the aryl groups above include phenyl groups, naphthyl groups, and the like. Examples of fluorine-substituted monovalent hydrocarbon groups include 3,3,3-trifluoropropyl and 3,3,4,4,5,5,6,6,6-nonafluorohexyl groups, but 3,3,3-trifluoropropyl groups are preferable. Examples of the alkoxy groups include methoxy groups, ethoxy groups, propoxy groups, and isopropoxy groups.

Here, from the viewpoint of ease of production of the branched polyorganosiloxane having a small polydispersity, as the substituent R excluding the phenolic hydroxyl group-containing group, the functional group R is preferably a group having a sterically large volume, and specifically, an alkyl group or an aryl group having 3 or more (preferably 3 to 20) carbon atoms is recommended as a preferable group.

The curable branched polyorganosiloxane of the present invention has a phenolic hydroxyl group-containing group in the molecule. Specifically, it is necessary that all or a part of the substituents Rs in the average unit formula (1) are phenolic hydroxyl group-containing groups, and at least one of the substituents Rs is a phenolic hydroxyl group-containing group. The phenolic hydroxyl group-containing group is preferably a group expressed by the following formula (2):

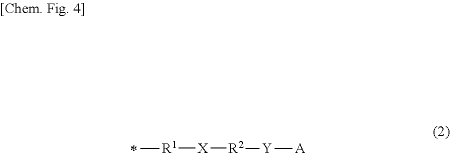

The linking group R¹ is a divalent hydrocarbon group having 2 to 6 carbon atoms, which may be linear or branched. Specifically, examples of the linking group R¹ include ethylene groups, propylene groups, 2-methylethylene groups, butylene groups, pentylene groups, hexylene groups, and the like, but propylene groups are preferable.

The linking group X is a divalent linking group containing an oxygen atom or a sulfur atom, and examples thereof include an ester group —O(C═O)— and a thioester group —S(C═O)—, and one or more divalent linking groups selected therefrom can be used. It is preferable that the linking group X should be an ester group —O(C═O)—.

The linking group R² is a divalent linking group having 2 or 3 carbon atoms. Specific examples thereof include an ethylene group and a methylethylene group.

The linking group Y is an oxygen atom or a sulfur atom, and is preferably a sulfur atom. The substituents As are a phenolic hydroxyl groups represented by the following formula (A1) or a substituted or unsubstituted aromatic hydrocarbon-containing groups represented by the following formula (A2), provided that at least one of the substituents As is A1.

On the other hand, the symbol * indicates a bonding site to the silicon atom on the organopolysiloxane.

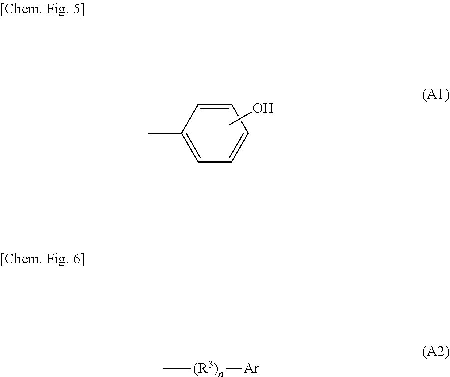

(wherein R³ is an alkylene group having 1 to 3 carbon atoms; n is 0 or 1; and Ar is a monovalent hydrocarbon group or an aromatic hydrocarbon group having 6 to 14 carbon atoms which may be substituted with a halogen group.)

The softening point of the branched polyorganosiloxane and the surface tack during thin film formation can be adjusted by introducing a substituent A2 into the phenolic hydroxyl group-containing group. Examples of R³ used herein include a methylene group, an ethylene group, and a propylene group, and a methylene group is preferable. The number of alkylene groups in these substituents A2 may be 0 and is preferably 0. Examples of the aromatic hydrocarbon group having 6 to 14 carbon atoms which may be substituted with a monovalent hydrocarbon group or a halogen group include a phenyl group, an o-tolyl group, a p-tolyl group, an o-chlorophenyl group, a p-chlorophenyl group, a 1-naphthyl group, a 2-naphthyl group, a 1-methyl-2-naphthyl group, a 6-methyl-2-naphthyl group, a 2-methyl-1-naphthyl group, a 2-anthracene group, and a 9-anthracene group. Among them, a 1-naphthyl group and a 2-naphthyl group are preferably used.

There is no limitation on the number of the A2 in the molecules, but from the viewpoint of maintaining favorable alkali solubility and high energy beam curability of the branched polyorganosiloxane, the value of [molar concentration of A2]/[molar concentration of A] is preferably 0.5 or less. A value of 0.2 or less is more preferred, and 0.1 or less is even more preferred.

The curable branched organopolysiloxane of the present invention has at least one phenolic hydroxyl group in the molecule, and the average number thereof is preferably 4 or more. That is, the branched organopolysiloxane of the present invention may be a branched organopolysiloxane having a single number of phenolic hydroxyl groups, or may be a optionally combined mixture of branched organopolysiloxanes having two or more different numbers of phenolic hydroxyl groups, but the average number of phenolic hydroxyl groups in all molecules of the curable branched organopolysiloxane is preferably 4 or more. As a result, a favorable high energy beam curability and an excellent alkali solubility can be imparted. The average number of the phenolic hydroxyl group-containing groups is preferably 5 or more, more preferably 6 or more on average. In particular, when the number of Si atoms is 12 or less, it is preferable to have 4 to 12 phenolic hydroxyl group-containing groups on average in the molecule, with the upper limit being the number of substituents R on the Si atoms.

The site of the phenolic hydroxyl group-containing group in the curable branched polyorganosiloxane of the present invention is not particularly limited, and can be applied to any R in the average unit formula (1). However, as described above, in consideration of satisfying the above formula (3) and preferably having four or more phenolic hydroxyl group-containing groups, all or a part of R in the monoorganosiloxy unit (RSiO_{3/2}) is preferably a phenolic hydroxyl group-containing group.

There are no particular limitations on the production method of the curable branched organopolysiloxane of the present invention. As a typical production method, the following production method 1) or 2) can be used:
1) performing a controlled hydrolysis/condensation reaction between a previously produced alkoxysilane containing a phenolic hydroxyl group and another alkoxysilane as an optional component to produce a branched organopolysiloxane having a predetermined molecular weight and a small polydispersity;
2) performing a controlled hydrolysis/condensation reaction using the same alkoxysilanes or a plurality of different alkoxysilanes to produce a reactive branched organopolysiloxane having a predetermined molecular weight and a low polydispersity, and then introducing, by a chemical reaction, a compound containing a phenolic hydroxyl group and an optional compound containing an aromatic hydrocarbon.

In the present invention, the production method 2) is preferably used. In addition, since heavy metals such as platinum atoms are not contained in the product by any of the above-described production methods, the production method is advantageous when applied to electronic materials, particularly electronic materials in the semiconductor field.

The method 2) will be further described with reference to specific examples. A mixture of a trialkoxysilane having a reactive carbon-carbon double bond-containing organic group such as a (meth) acryloyl group and optionally usable other trialkoxysilanes is subjected to a controlled hydrolysis/condensation reaction in the presence of a basic catalyst to produce a reactive branched organopolysiloxane having a low polydispersity. The molecular weight of the product can be controlled by the kind and amount of the solvent and the amount of water used during the reaction, and it is particularly preferable that the reactive branched organopolysiloxane at this stage should have the above-mentioned cage-like molecular structure.

A curable branched organopolysiloxane having a phenolic hydroxyl group can be produced by an addition reaction between: the resulting reactive branched organopolysiloxane having a (meth) acryloyl group in the molecule (preferably having a cage-like molecular structure with a low polydispersity); and a compound having a mercapto group-containing phenol compound and an optionally usable compound having both a mercapto group and an aromatic hydrocarbon group. In the production method 2), it is particularly preferable that the phenol compound containing a (meth) acryloyl group and a mercapto group be added at a ratio of 1:1 or at a ratio with an excess amount of the phenol compound so that no reactive carbon-carbon double bond-containing organic group such as a (meth) acryloyl group remains in the resulting curable branched organopolysiloxane from the viewpoint of alkali solubility of the curable branched organopolysiloxane and high-precision patterning properties (including coatability).

### [High Energy Beam-Curable Composition]

The high energy beam-curable composition of the present invention contains the following four components. Component (A) is the main component of the present invention as described in detail above.
(A) The aforementioned curable branched organopolysiloxane;
(B) A photoacid generating agent in an amount of 0.1 to 20 parts by mass per 100 parts by mass of the component (A);
(C) A crosslinking agent in an amount of 1 to 30 parts by mass per 100 parts by mass of the component (A);
and
(D) An organic solvent.

### [Component (B): Photoacid Generating Agent]

Component (B) is a component that catalyzes the curing reaction of component (A) by a high energy beam, and a group of compounds known as photoacid generating agents for polymerization is usually applicable. Known photoacid generating agents are compounds capable of generating a Bronsted-Lowry acid or a Lewis acid upon irradiation with a high energy beam or electron beam.

The photoacid generating agent used in the high energy beam-curable composition of the present invention can be arbitrarily selected from those known in the art and is not particularly limited to a specific type. Strong acid-generating compounds, such as diazonium salts, sulfonium salts, iodonium salts, phosphonium salts, and the like, are known photoacid generating agents, and these can be used. Examples of the photoacid generating agent include, but are not limited to, bis(4-tert-butylphenyl)iodonium hexafluorophosphate, cyclopropyldiphenylsulfonium tetrafluoroborate, dimethylphenacylsulfonium tetrafluoroborate, diphenyliodonium hexafluorophosphate, diphenyliodonium hexafluoroarsenate, diphenyliodonium tetrafluoromethanesulfonate, 2-(3,4-dimethoxystyryl)-4,6-bis(trichloromethyl)-1,3,5-triazine, 2-[2-(furan-2-yl)vinyl]-4,6-bis(trichloromethyl)-1,3,5-triazine, 4-isopropyl-4′-methyldiphenyliodonium tetrakis(pentafluorophenyl)borate, 2-[2-(5-methylfuran-2-yl)vinyl]-4,6-bis(trichloromethyl)-1,3,5-triazine, 2-(4-methoxyphenyl)-4,6-bis(trichloromethyl)-1,3,5-triazine, 2-(4-methoxystylyl)-4,6-bis(trichloromethyl)-1,3,5-triazine, 4-nitrobenzenediazonium tetrafluoroborate, triphenylsulfonium tetrafluoroborate, triphenylsulfonium bromide, tri-p-tolylsulfonium hexafluorophosphate, tri-p-tolylsulfonium trifluoromethanesulfonate, diphenyliodonium triflate, triphenylsulfonium triflate, diphenyliodonium nitrate, bis(4-tert-butylphenyl)iodonium perfluoro-1-butane sulfonate, bis(4-tert-butylphenyl)iodonium triflate, triphenylsulfonium perfluoro-1-butanesulfonate, N-hydroxynaphthalimide triflate, p-toluene sulfonate, diphenyliodonium p-toluenesulfonate, (4-tert-butylphenyl) diphenylsulfonium triflate, tris(4-tert-butylphenyl)sulfonium triflate, N-hydroxy-5-norbornene-2,3-dicarboxymide perfluoro-1-butanesulfonate, (4-phenylthiophenyl) diphenylsulfonium triflate, 4-(phenylthio) phenyldiphenylsulfonium triethyltrifluorophosphate, and the like. In addition to the aforementioned compounds, examples of the photocationic polymerization initiator include commercially available photoacid generating agents, such as Omnicat 250, Omnicat 270 (both manufactured by IGM Resins BV), CPI-310B, IK-1 (both manufactured by San-Apro Co., Ltd.), DTS-200 (Midori Kagaku Co., Ltd.), TS-01, TS-91 (both manufactured by Sanwa Chemical Co., Ltd.), Irgacure 290 (BASF), and the like.

The amount of photoacid generating agent added to the high energy beam-curable composition of the present invention is not particularly limited, so long as the desired photocuring reaction occurs, but the photoacid generating agent is generally preferably used in an amount of 0.1 to 20 parts by mass, preferably 0.5 to 20 parts by mass, and particularly 1 to 10 parts by mass, per 100 parts by mass of the curable branched organopolysiloxane, which is component (A) of the present invention.

### [Component (C): Crosslinking Agent]

Component (C) is a component which reacts with a phenolic hydroxyl group in the component (A) by the action of an acid generated from component (B) due to irradiation with a high energy beam, and contributes to a crosslinking reaction.

Component (C) can be a known crosslinking agent that is blended in a chemically amplified negative resist composition.

Examples of component (C) that are preferably used in the present invention include compounds having a plurality of alkoxymethyl groups on an amino group of an amino compound such as melamine, acetoguanamine, urea, ethyleneurea, glycoluril, and the like. Specific examples include hexamethoxymethylmelamine, tetramethoxymethylmonohydroxymethylmelamine, tetrakismethoxymethylglycoluril, tetrakisbutoxymethylglycoluril, dimethoxymethyldimethoxyethyleneurea, and the like. Of these, urea compounds, tetrakismethoxymethylglycoluril, tetrakisbutoxymethylglycoluril, and dimethoxymethyldimethoxyethyleneurea are preferably used. In addition to the aforementioned compounds, examples of component (C) include commercially available crosslinking agents such as Nikalac MW-390, MX-270, MX-279, MX-280 (all manufactured by Sanwa Chemical Co., Ltd.), and the like.

The amount of the crosslinking agent added to the high energy beam-curable composition of the present invention is not particularly limited so long as the desired photocuring reaction occurs. In the present invention, the crosslinking agent is generally used preferably in an amount of 1 to 30 parts by mass, preferably 5 to 30 parts by mass, and particularly 10 to 30 parts by mass, per 100 parts by mass of the curable branched organopolysiloxane, which is component (A) of the present invention.

### [Component (D): Organic Solvent]

The high energy beam-curable composition of the present invention preferably contains (D) an organic solvent for the purposes of adjusting the coatability of the curable branched organopolysiloxane and the thickness of the coating film, as well as for improving the dispersibility of the photoacid generating agent, and the like. These organic solvents can be organic solvents that have been conventionally blended in various high energy beam-curable compositions, without any particular restrictions.

Suitable examples of the organic solvent include: (poly)alkylene glycol monoalkyl ethers such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, propylene glycol monoethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, and the like; (poly)alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate (PGMEA), propylene glycol monoethyl ether acetate, and the like; other ethers such as diethylene glycol dimethyl ether, diethylene glycol methyl ethyl ether, and diethylene glycol diethyl ether; ketones such as methyl ethyl ketone, methyl isobutyl ketone, cyclohexanone, 2-heptanone, 3-heptanone, 4-heptanone, 5-methyl-3-heptanone, 2,4-dimethyl-3-pentanone, 2,6-dimethyl-4-heptanone, and the like; alkyl lactates such as methyl 2-hydroxypropionate, ethyl 2-hydroxypropionate, and the like; other esters such as ethyl 2-hydroxy-2-methylpropionate, methyl-3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanate, 3-methoxybutylacetate, 3-methyl-3-methoxybutylacetate, 3-methyl-3-methoxybutyl propionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate, ethyl 2-oxobutanoate, and the like; aromatic hydrocarbons such as toluene, xylene, mesitylene, cumene, propylbenzene, diethylbenzene, 1,3-diisopropylbenzene, and the like; and aromatic ethers such as anisole, phenethol, 2-methoxytoluene, 3-methoxytoluene, 4-methoxytoluene, 3,4-dimethoxytoluene, 1,4-bis(methoxymethyl)benzene, and the like. The organic solvent may be used alone or in combination with a plurality of organic solvents, taking into consideration the miscibility with component (A) to component (C).

The amount of organic solvent is not particularly limited, and is set appropriately based on the miscibility with (A) curable branched organopolysiloxane, the film thickness of the coating film formed by the high energy beam-curable composition, and the like. Typically, an amount of 50 to 10,000 parts by mass per 100 parts by mass of the component (A) is used. In other words, a solvent concentration of 1 to 50 mass % of curable branched organopolysiloxane is preferable, and a range of 2 to 40 mass % is more preferable.

The cured product obtained from the high energy beam-curable composition of the present invention can be designed so that the desired physical properties of the cured product and the curing speed of the curable composition can be obtained according to the molecular structure of component (A) and the number of phenolic hydroxyl groups per molecule, and according to the molecular structure and amount of component (B) and component (C) added, and the viscosity of the curable composition can be designed to achieve the desired value according to the amount of component (D). Furthermore, the cured product obtained by curing the high energy beam-curable composition of the present invention is also included in the scope of the present invention. The shape of the cured product obtained from the curable composition of the present invention is not particularly limited, and it may be a thin film coating layer, may be a sheet-like molded product or the like, or may be used as a sealing material for a laminated body, display device, or the like or as an intermediate layer. The cured product obtained from the composition of the present invention is preferably in the form of a thin film coating layer, and is particularly preferably a thin film insulative coating layer and/or resist layer.

The high energy beam-curable composition of the present invention is suitably used as a coating agent, particularly as an insulative coating agent for an electronic device or electrical device. The composition is also suitable for use as a resist material when using short wavelength light such as EUV, an excimer laser, or the like as a light source.

### [Other Additives]

In addition to the aforementioned components, additional additives may be added to the composition of the present invention if desired. Examples of additives include, but are not limited to, those described below.

### [Adhesion-Imparting Agent]

An adhesion-imparting agent can be added to the high energy beam-curable composition of the present invention to improve adhesion and close-fitting properties to a substrate in contact with the composition. When the curable composition of the present invention is used for applications such as coating agents, sealing materials, and the like that require adhesion or close-fitting properties to a substrate, an adhesion-imparting agent is preferably added to the curable composition of the present invention. An arbitrary known adhesion-imparting agent can be used, so long as the adhesion-imparting agent does not interfere with a curing reaction of the composition of the present invention.

Examples of the adhesion-imparting agent that can be used in the present invention include: organosilanes having a trialkoxysiloxy group (such as a trimethoxysiloxy group or a triethoxysiloxy group) or a trialkoxysilylalkyl group (such as a trimethoxysilylethyl group or triethoxysilylethyl groups) and a hydrosilyl group or an alkenyl group (such as a vinyl group or an allyl group), or organosiloxane oligomers having a linear structure, branched structure, or cyclic structure with approximately 4 to 20 silicon atoms; organosilanes having a trialkoxysiloxy group or a trialkoxysilylalkyl group and a methacryloxyalkyl group (such as a 3-methacryloxypropyl group), or organosiloxane oligomers having a linear structure, branched structure, or cyclic structure with approximately 4 to 20 silicon atoms; organosilanes having a trialkoxysiloxy group or a trialkoxysilylalkyl group and an epoxy group-bonded alkyl group (such as a 3-glycidoxypropyl group, a 4-glycidoxybutyl group, a 2-(3,4-epoxycyclohexyl)ethyl group, or a 3-(3,4-epoxycyclohexyl)propyl group), or organosiloxane oligomers having a linear structure, branched structure, or cyclic structure with approximately 4 to 20 silicon atoms; organic compounds having two or more trialkoxysilyl groups (such as trimethylsilyl groups or triethoxysilyl groups); reaction products of aminoalkyltrialkoxysilane and epoxy group-bonded alkyltrialkoxysilane, and epoxy group-containing ethyl polysilicate. Specific examples thereof include vinyl trimethoxysilane, allyl trimethoxysilane, allyl triethoxysilane, hydrogen triethoxysilane, 3-glycidoxypropyl trimethoxysilane, 3-glycidoxypropyl triethoxysilane, 2-(3,4-epoxycyclohexyl)ethyl trimethoxysilane, 3-methacryloxypropyl trimethoxysilane, 3-methacryloxypropyl triethoxysilane, 1,6-bis(trimethoxysilyl)hexane, 1,6-bis(triethoxysilyl)hexane, 1,3-bis[2-(trimethoxysilyl)ethyl]-1,1,3,3-tetramethyldisiloxane, reaction products of 3-glycidoxypropyl triethoxysilane and 3-aminopropyl triethoxysilane, condensation reaction products of a methylvinyl siloxane oligomer blocked with a silanol group and a 3-glycidoxypropyl trimethoxysilane, condensation reaction products of a methylvinyl siloxane oligomer blocked with a silanol group and a 3-methacryloxypropyl triethoxysilane, and tris(3-trimethoxysilylpropyl)isocyanurate.

The amount of the adhesion-imparting agent to be added to the high energy beam-curable composition of the present invention is not particularly limited. However, since it does not promote curing properties of the curable composition or discoloration of a cured product, the amount is preferably within a range of 0.01 to 5 parts by mass, or within a range of 0.01 to 2 parts by mass, relative to a total of 100 parts by mass of component (A).

### [Additional Optional Additives]

Another additive may be added to the high energy beam-curable composition of the present invention in addition to or in place of the adhesion-imparting agent described above, if desired. Examples of additives that can be used include leveling agents, silane coupling agents not included in those listed above as adhesion-imparting agents, high energy beam absorbers, antioxidants, polymerization inhibitors, fillers (reinforcing fillers, insulating fillers, thermal conductive fillers, and other functional fillers), and the like. If necessary, an appropriate additive can be added to the composition of the present invention. Furthermore, a thixotropy imparting agent may also be added to the composition of the present invention if necessary, particularly when used as a sealing agent.

### [Method of Manufacturing Cured Film]

The method of producing the cured film is not particularly limited, so long as the method is capable of curing the film made of the high energy beam-curable composition described above. Known lithographic processes can be preferably applied to produce a patterned cured film. A typical recommended manufacturing method preferably includes:
1) forming a coating film of the aforementioned high energy beam-curable composition on a substrate;
2) heating the resulting coating film for a short period of time at a temperature of about 100° C. or less to remove the solvent;
3) performing position-selective exposure of the coating film;
4) developing the exposed coating film; and
5) heating the patterned cured film to a temperature exceeding 100° C. to fully cure the film.

If necessary, a short heating step can be inserted between steps 3) and 4).

This manufacturing method is described below in detail. The substrate is not particularly limited, and various substrates can be used as the substrate, including glass substrates, silicon substrates, glass substrates coated with transparent conductive films, and the like.

Known methods for applying the high energy beam-curable composition on a substrate use a coating device such as spin coaters, roll coaters, bar coaters, slit coaters, and the like.

The applied curable composition is usually heated and dried to remove the solvent. Typical methods include drying on a hot plate or in an oven at 80 to 120° C., preferably 90 to 100° C. for 1 to 2 minutes, and leaving at room temperature for several hours, or heating in a hot air heater or infrared heater for tens of minutes to several hours, and the like.

Position-selective exposure of the coating film is usually performed through a photomask or the like, using a known active energy beam light source, such as high energy beam sources like high-pressure mercury vapor lamps, metal halide lamps, and LED lamps, laser light sources such as excimer laser lights, and UEV. Negative or positive type photomasks can be used, depending on the properties of the curable composition. The energy beam dose to be irradiated depends on the structure of the curable composition, but typically ranges from 50 to 2,000 mJ/cm². Furthermore, if necessary, the composition coating film after exposure may be subjected to a heat treatment (post-exposure bake (PEB)) to enhance the degree of curing. The conditions for this are usually a temperature of 100 to 150° C. for a period of 1 to 1.5 minutes.

Development using a developing solution is performed in order to form a pattern with the desired shape. Aqueous alkali solutions and organic solvents are known as developer solutions, but development with an aqueous alkali solution is the most common. Both aqueous solutions of inorganic bases and aqueous solutions of organic bases can be used as the aqueous alkali solution. Suitable developing solutions include basic aqueous solutions such as sodium hydroxide, potassium hydroxide, sodium carbonate, ammonia, quaternary ammonium salts, and the like. Aqueous solutions of tetramethylammonium hydroxide (TMAH) are particularly preferable. The developing method is not particularly limited, and for example, a dipping method, spray method, or the like can be used.

As described above, the curable branched organopolysiloxane according to the present invention and the high energy beam-curable composition containing this compound as a main component will have excellent high energy beam curability while also having particularly excellent alkali solubility, and therefore have the advantages in which pattern formation can be carried out easily and with high precision, particularly when subjected to a development step using an aqueous alkali solution, and in which the obtained cured film has excellent mechanical strength and transparency.

It is preferable that a post-exposure bake should be usually performed on the patterned cured films after development. The post-heating temperature is not particularly limited so long as no thermal decomposition or deformation occurs in the patterned cured film, but a temperature of 150 to 250° C. is preferable, and 150 to 200° C. is more preferable.

The aforementioned operations can form a cured film of high energy beam-curable composition patterned with a desired shape.

### Application

Specifically, the high energy beam-curable composition of the present invention is particularly useful as a material for forming an insulating layer for various articles, particularly electronic and electrical devices and as a resist material. Furthermore, the curable composition of the present invention provides favorable transparency of the cured product obtained therefrom, and is also suitable as a material for forming an insulating layer for touch panels, displays and other display devices. In this case, an arbitrary desired pattern may be formed as described above if necessary on the insulating layer. Therefore, a display device such as a touch panel, display, or the like containing an insulating layer obtained by curing the high energy beam-curable composition of the present invention is also an aspect of the present invention.

Furthermore, the curable composition of the present invention can also be used to form an insulating coating layer (insulating film) by curing after coating an article. Therefore, the composition of the present invention can be used as an insulative coating agent. Furthermore, a cured product formed by curing the curable composition of the present invention can be used as an insulative coating layer.

An insulating film formed from the curable composition of the present invention can be used for various applications other than the aforementioned display device. In particular, use is possible as a component of an electronic device or as a material used in a process of manufacturing the electronic device. Electronic devices include semiconductor devices, magnetic recording heads, and other electronic apparatuses. For example, the curable composition of the present invention can be used in an insulating film of a semiconductor device, such as an LSI, system LSI, DRAM, SDRAM, RDRAM, D-RDRAM, or a multi-chip module multilayer circuit board, an interlayer insulating film for a semiconductor, an etch stopper film, a surface protection film, a buffer coat film, a passivation film in LSI, a cover coat for a flexible copper cladding plate, a solder resistant film, and a surface protection film for an optical device.

The present invention is further described below on the basis of Examples, but the present invention is not limited to the Examples below.

### EXAMPLES

Synthesis of the curable branched organopolysiloxane, preparation and evaluation of a high energy beam-curable composition, and preparation and evaluation of a cured product thereof of the present invention will now be described in detail with reference to examples.

### [Appearance of Curable Composition and Cured Product]

The curable composition and cured product were visually observed to determine the appearance, including the transparency.

### [Alkali Solubility of Curable Branched Organopolysiloxane]

A 20 mass % PGMEA solution of each curable branched organopolysiloxane was spin-coated onto an optical glass substrate to a thickness of 0.3 to 0.5 μm, and heated (pre-baked) at 90° C. for 1.5 minutes using a hot plate to form a coating film. The film was then developed in a 2.38% aqueous solution of tetramethylammonium hydroxide (TMAH) at 25° C. for 1 minute, followed by an immersion water wash in a water bath at room temperature (25° C.). The water wash time was 15 seconds. After rinsing and drying to remove water, the glass substrate was visually observed to determine the solubility (developability) in alkali solutions using the following criteria.
A: Completely dissolved: Coating film is completely removed
B: Almost dissolved: A small amount of paint residue (scum) is observed
C: Partially dissolved: Large amount of scum (more than 20% of coating film area) observed
D: Insoluble

### [High Energy Beam Curability of Curable Composition]

A PGMEA solution of each curable composition (curable branched organopolysiloxane concentration: 20 mass %) was used to form a coating film of the curable composition by the same method as above. The coating film was irradiated with a high-energy beam (254 nm, light intensity: 40 mJ/cm²) using a high-pressure mercury lamp and then heated at 150° C. for 2 minutes to obtain a cured coating film. The high energy beam curability was determined using the following criteria.
A: Cured coating film is insoluble in the TMAH dissolution test
B: Only the edge portions of the cured coating film (less than 5% of the total area of the cured coating film) are dissolved in the TMAH dissolution test
C: Cured coating film is completely or almost completely dissolved in the TMAH dissolution test

### [Synthesis Example 1] Synthesis of methacrylate-functional branched organopolysiloxane (P-1)

A 500 mL three-necked flask equipped with a thermometer, a stirrer, and a nitrogen-introducing tube was charged with 90.0 g of methacryloxypropyltrimethoxysilane, 360 g of tetrahydrofuran, 1.0 g of 50% aqueous cesium hydroxide solution, and 9.9 g of water. This mixture was refluxed at 70° C. for 4 hours to carry out hydrolysis and condensation reaction. After cooling to room temperature, 8.0 g of KYOWAAD® 700PL manufactured by Kyowa Chemical Industry Co., Ltd. was added thereto, and the mixture was stirred at room temperature for 30 minutes. Solid was separated by filtration and volatile components were distilled off under reduced pressure to obtain a colorless oily product. ¹³C and ²⁹SiNMR spectroscopy and gel permeation chromatography (GPC) analysis confirmed that the product was a branched organopolysiloxane (P-1) in which all the substituents on the silicon atoms were methacryloxypropyl groups. The number average molecular weight (Mn), weight average molecular weight (Mw), and polydispersity index (PDI) in terms of standard polystyrene as determined by GPC were 1,430, 1,460, and 1.02, respectively. The average number of silicon atoms (the value being calculated from the above Mn) was 8.0.

### [Synthesis Example 2] Synthesis of Methacrylate- and Phenyl-Functional Branched Organopolysiloxane (P-2)

A 500 mL three-necked flask equipped with a thermometer, a stirrer, and a nitrogen introduction tube was charged with 65.0 g of methacryloxypropyltrimethoxysilane, 31.1 g of phenyltrimethoxysilane, 200 g of tetrahydrofuran, 1.0 g of 50% aqueous cesium hydroxide solution, and 11.6 g of water. The same operation as in Synthesis Example 1 was carried out to obtain a colorless oily product. The same characterization as in Synthesis Example 1 confirmed that the product was a branched organopolysiloxane (P-2) in which 63 mol % of the substituents on the silicon atoms were methacryloxypropyl groups and 37 mol % were phenyl groups. The standard polystyrene equivalent Mn, Mw, and PDI as determined by GPC were 1,260, 1,460, and 1.16, respectively. The average number of silicon atoms (the value being calculated from the above Mn) was 8.0.

### [Synthesis Example 3 (Example)] Synthesis of phenol-functional branched organopolysiloxane (A-1)

A 500 mL three-necked flask equipped with a thermometer, a stirrer, and a nitrogen introduction tube was charged with 38.0 g of P-1 obtained in Synthesis Example 1, 27.0 g of 4-mercaptophenol, and 60.0 g of propylene glycol monomethyl ether acetate (PGMEA) to obtain a homogeneous solution. To this solution, was slowly added dropwise 21.5 g of triethyl amine at room temperature, and the resultant mixture was further stirred for 4 hours to complete the reaction. 13.0 g of acetic acid was added to the mixture and the reaction liquid was washed with 200-mL water three times. The organic layer was treated with anhydrous magnesium sulfate, and the solid was separated by filtration to obtain a PGMEA solution of the product. The same characterization as in Synthesis Example 1 was carried out. No side reaction occurred, and it was confirmed that the product was a branched organopolysiloxane (A-1) in which the substituent on the silicon atom had a structure having 4-mercaptophenol added to a methacryloxypropyl group. The standard polystyrene equivalent Mn, Mw, and PDI as determined by GPC were 2,680, 2,730, and 1.02, respectively.

### [Synthesis Example 4 (Example)] Synthesis of phenol-functional branched organopolysiloxane (A-2)

A PGMEA solution of product was obtained by carrying out a reaction in a similar manner to the one in Synthesis Example 3 except that 43.0 g of P-1, 27.0 g of 4-mercaptophenol, 3.9 g of 2-naphthalenethiol, 60.0 g of PGMEA, 24.0 g of triethyl amine, and 14.0 g of acetic acid were used in place of 38.0 g of P-1, 27.0 g of 4-mercaptophenol, 60.0 g of PGMEA, 21.5 g of triethyl amine, and 13.0 g of acetic acid. The same characterization as in Synthesis Example 1 was carried out. No side reaction occurred, and it was confirmed that the product was a branched organopolysiloxane (A-2) in which 4-mercaptophenol and 2-naphthalenethiol were added to a methacryloxypropyl group at a molar ratio of 90:10 as a substituent on the silicon atom. The standard polystyrene equivalent Mn, Mw, and PDI as determined by GPC were 2,730, 2,920, and 1.07, respectively.

### [Synthesis Example 5 (Example)] Synthesis of phenol- and phenyl-functional branched organopolysiloxane (A-3)

A PGMEA solution of product was obtained by carrying out a reaction in a similar manner to the one in Synthesis Example 3 except that 52.0 g of P-2, 26.0 g of 4-mercaptophenol, 60.0 g of PGMEA, 16.5 g of triethyl amine, and 10.0 g of acetic acid were used in place of 38.0 g of P-1, 27.0 g of 4-mercaptophenol, 60.0 g of PGMEA, 21.5 g of triethyl amine, and 13.0 g of acetic acid. The same characterization as in Synthesis Example 1 was carried out. No side reaction occurred, and it was confirmed that the product was a branched organopolysiloxane (A-3) in which the substituent on the silicon atom had a structural unit in which 4-mercaptophenol was added to a methacryloxypropyl group and a phenyl group unit at a molar ratio of 63:37. The standard polystyrene equivalent Mn, Mw, and PDI as determined by GPC were 2,100, 2,420, and 1.15, respectively.

### [Synthesis Example 6] Synthesis of methacrylate- and phenyl-functional branched organopolysiloxane (P-3)

A 500 mL three-necked flask equipped with a thermometer and a nitrogen introduction tube was charged with 143.8 g of 3-methacryloxypropyl trimethoxysilane, 67.5 g of phenyltrimethoxysilane, 150 g of toluene, 45 g of water, and 1.6 g of a 50% aqueous solution of cesium hydroxide and the resultant mixed solution was stirred at 80° C. for 4 hours. Azeotropic dehydration and demethanolization was performed using toluene, and then the product was concentrated to 80% solids and stirred at 115° C. for another 6 hours. The solution was then allowed to stand at room temperature, and 20 g of an alkaline adsorbing agent (Kyoward® KW-700PL) was added. After stirring for 30 minutes at room temperature, the solid content was filtered to obtain a solution of branched polysiloxane with a solid content of 80%. The same characterization as in Synthesis Example 1 confirmed that the product was a toluene solution of a branched polysiloxane (P-3) in which 63 mol % of the substituents on the silicon atoms were methacryloxypropyl groups and 37 mol % were phenyl groups. The standard polystyrene equivalent Mn, Mw, and PDI as determined by GPC were 2,200, 5,280, and 2.40, respectively. The average number of silicon atoms (value calculated from the above Mn) was 13.7.

### [Synthesis Example 7] Synthesis of phenol- and phenyl-functional branched organopolysiloxane (A-4)

To the solution of P-3, was added PGMEA in an amount of 120% by mass or more based on the solid content (mass of P-3) in the solution of P-3 synthesized as described above, and toluene and PGMEA were distilled off under reduced pressure to prepare a 50% PGMEA solution of P-3. Except that 24.8 g of 4-mercaptophenol, 10.0 g of PGMEA, 16.5 g of triethyl amine, and 10.0 g of acetic acid were used in 100 g of the resultant solution, a reaction was carried out in a similar manner to the one in Synthesis Example 3 to obtain a PGMEA solution of products. The same characterization as in Synthesis Example 1 was carried out. No side reaction occurred, and it was confirmed that the product was a branched organopolysiloxane (A-4) in which the substituent on the silicon atom had a structural unit in which 4-mercaptophenol was added to a methacryloxypropyl group and a phenyl group unit at a molar ratio of 63:37. The standard polystyrene equivalent Mn, Mw, and PDI as determined by GPC were 3,300, 7,950, and 2.41, respectively.

### [Example 1 and Comparative Example 1] Alkali solubility of branched organopolysiloxane

The alkali solubility was evaluated using a 20 mass % PGMEA solution of the branched organopolysiloxane shown below, and the results are compiled in Table 1. Note that the compounds corresponding to Examples of the present application are curable branched organopolysiloxanes of A-1 to A-3.
A-1: Curable branched organopolysiloxane obtained in Synthesis Example 3
A-2: Curable branched organopolysiloxane obtained in Synthesis Example 4
A-3: Curable branched organopolysiloxane obtained in Synthesis Example 5
A-4: Curable branched organopolysiloxane obtained in Synthesis Example 7
P-1: Curable branched organopolysiloxane obtained in Synthesis Example 1
P-2: Curable branched organopolysiloxane obtained in Synthesis Example 2
P-3: Curable branched organopolysiloxane obtained in Synthesis Example 6

TABLE 1

| | Example/Comparative Example | | | | | | |
|---|---|---|---|---|---|---|---|
| | Example 1 | | | Comparative Example 1 | | | |
| Component | A-1 | A-2 | A-3 | A-4 | P-1 | P-2 | P-3 |
| Weight Average | 2,730 | 2,920 | 2,420 | 7,950 | 1,460 | 1,460 | 5,280 |
| Molecular Weight | | | | | | | |
| PDI | 1.02 | 1.07 | 1.15 | 2.41 | 1.02 | 1.16 | 2.40 |
| Number of | 8.0 | 8.0 | 8.0 | 13.7 | 8.0 | 8.0 | 13.7 |
| silicon atoms | | | | | | | |
| Alkali solubility | A | A | A | B to C | D | D | D |
| evaluation | | | | | | | |

### [Examples 2 and Comparative Example] Evaluation of Curable Branched Organopolysiloxane Compositions

The following PGMEA solutions of a branched organopolysiloxane, crosslinking agent, and curing catalyst were mixed in the compositions shown in Table 2 (parts by mass; branched organopolysiloxane is calculated on the basis of solid content), and the mixtures were filtered through a membrane filter having a pore size of 0.2 μm to prepare high energy beam-curable compositions.

### Curable Branched Organopolysiloxanes (20 Mass % PGMEA Solution):

A-1: Curable branched organopolysiloxane obtained in Synthesis Example 3
A-2: Curable branched organopolysiloxane obtained in Synthesis Example 4
A-3: Curable branched organopolysiloxane obtained in Synthesis Example 5
A-4: Curable branched organopolysiloxane obtained in Synthesis Example 7
P-1: Curable branched organopolysiloxane obtained in Synthesis Example 1
P-2: Curable branched organopolysiloxane obtained in Synthesis Example 2
P-3: Curable branched organopolysiloxane obtained in Synthesis Example 6

### Photoacid Generating Agent:

B-1: Tri-p-tolylsulfonium trifluoromethanesulfonate (TS-01; manufactured by Sanwa Chemical Co., Ltd.) Curing agent:
C-1: Tetrakis methoxymethyl glycoluril (Nikalac MX-270; manufactured by Sanwa Chemical Co., Ltd.)

### Photoradical Initiator:

D-1: bis (2, 4, 6-trimethylbenzoyl) phenylphosphine oxide (Omnirad 819, manufactured by IGM Resins B.V.)

TABLE 2

| | Example | Example | Example | Comparative | Comparative | Comparative | Comparative |
|---|---|---|---|---|---|---|---|
| Component | 2-1 | 2-2 | 2-3 | Example 2-1 | Example 2-2 | Example 2-3 | Example 2-4 |
| (A-1; as | 100 | | | | | | |
| solid content) | | | | | | | |
| (A-2; as | | 100 | | | | | |
| solid content) | | | | | | | |
| (A-3; as | | | 100 | | | | |
| solid content) | | | | | | | |
| (A-4; as | | | | 100 | | | |
| solid content) | | | | | | | |
| (P-1; as | | | | | 100 | | |
| solid content) | | | | | | | |
| (P-2; as | | | | | | 100 | |
| solid content) | | | | | | | |
| (P-3; as | | | | | | | 100 |
| solid content) | | | | | | | |
| (B-1) | 3 | 3 | 3 | 3 | | | |
| (C-1) | 20 | 20 | 10 | 10 | | | |
| (D-1) | | | | | 2 | 2 | 2 |
| Total | 123 | 123 | 113 | 113 | 102 | 102 | 102 |
| Appearance | Transparent | Transparent | Transparent | Transparent | Transparent | Transparent | Transparent |
| of curable | | | | | | | |
| composition | | | | | | | |
| High energy | A | A | A | A | A | A | A |
| beam curability | | | | | | | |
| Appearance | Transparent | Transparent | Transparent | Transparent | Transparent | Transparent | Transparent |
| of cured product | | | | | | | |
| Alkali | A | A | A | B to C | D | D | D |
| solubility | | | | | | | |

As shown in Table 1, the coating films (Examples 1: A-1 to A-3) formed from the curable branched organopolysiloxane of the present invention exhibited an excellent alkali solubility. Furthermore, as shown in Table 2, the high energy beam-curable organopolysiloxane compositions of the present invention (Examples 2-1, 2-2, and 2-3) had favorable high energy beam curability. Furthermore, the cured coating film formed by irradiation with a high energy beam was transparent and exhibited sufficiently high coating toughness.

On the other hand, the coating films formed from organopolysiloxanes having no phenolic hydroxyl group-containing group or having a molecular weight or polydispersity outside the scope of the present invention (Comparative Example 1: A-4, P-1 to P-3) had insufficient alkali solubilities. Furthermore, it was confirmed that the high energy beam-curable compositions using the branched polyorganosiloxane having no phenolic hydroxyl group (Comparative Examples 2-2, 2-3, and 2-4) and the phenolic hydroxyl group-containing branched polyorganosiloxane having a large weight average molecular weight and polydispersity (Comparative Example 2-1) had inferior alkali solubilities and thus are not suitable as a patterning materials.

### INDUSTRIAL APPLICABILITY

The curable branched organopolysiloxane according to the present invention and the high energy beam-curable composition containing the same as a main component have excellent high energy beam-curability, and have excellent alkali solubilities due to the low molecular weight and the small polydispersity of the main component. Therefore, when a development process using an aqueous alkali solution is carried out, there is an advantage that the pattern formation can be carried out easily but with high precision, and that the mechanical strength and transparency of the obtained cured film are excellent. Hence, the organopolysiloxanes and the like are particularly suitable as materials, especially patterning materials, coating materials, and resist materials for forming insulating layers, in particular, for touch panels and display devices such as displays, especially flexible displays.

1. A curable branched organopolysiloxane represented by the following average unit formula (1): 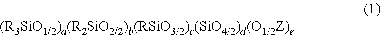
(wherein R is a group selected from an unsubstituted or fluorine-substituted monovalent hydrocarbon group, an alkoxy group, a hydroxyl group and a phenolic hydroxyl group-containing group; a, b, c, d, and e are numbers satisfying the following conditions: 0≤a, 0≤b, 0<c, 0≤d, 0≤e, 0.8≤c/(a+b+c+d+e), and at least one phenolic hydroxyl group-containing group is present in the molecule.)

2. The curable branched organopolysiloxane according to claim 1, wherein the weight average molecular weight is 3,500 or less.

3. The curable branched organopolysiloxane according to claim 1, wherein the a is 0, the b is 0, and the d is 0.

4. The curable branched organopolysiloxane according to claim 1, wherein the phenolic hydroxyl group-containing group is represented by the following general formula (2): 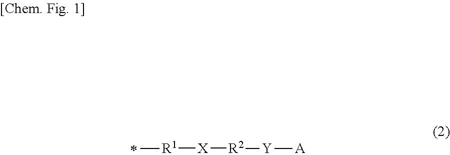
(wherein R¹ is a divalent hydrocarbon group having 2 to 6 carbon atoms; X is an oxygen atom- or sulfur atom-containing divalent linking group; R² is a divalent linking group having 2 or 3 carbon atoms; Y is an oxygen atom or a sulfur atom; the substituent A is a phenolic hydroxyl group represented by the following formula (A1) or a substituted or unsubstituted aromatic hydrocarbon-containing group represented by the following formula (A2), and * is a silicon atom-bonding site on the organopolysiloxane; provided that at least one of As is A1). 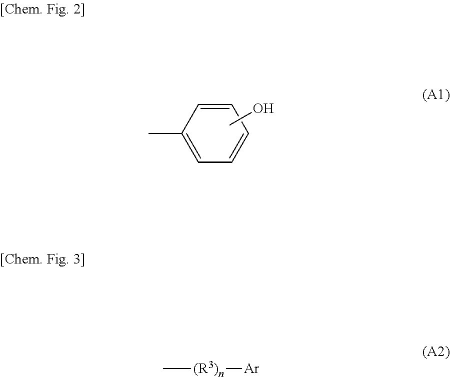
(wherein R³ is an alkylene group having 1 to 3 carbon atoms; n is 0 or 1; and Ar is a monovalent hydrocarbon group or an aromatic hydrocarbon group having 6 to 14 carbon atoms which may be substituted with a halogen group).

5. The curable branched organopolysiloxane according to claim 1, wherein X is at least one divalent linking group selected from an ester group —O(C═O)— and a thioester group —S(C═O)—; and Y is a sulfur atom.

6. The curable branched organopolysiloxane according to claim 1, having a polydispersity of 1.2 or less and having a cage-like molecular structure.

7. The curable branched organopolysiloxane according to claim 1, having an average number of silicon atoms in a molecule of 12 or less.

8. The curable branched organopolysiloxane according to claim 1, having, on average, 4 or more phenolic hydroxyl group-containing groups per molecule.

9. The curable branched organopolysiloxane according to claim 1, wherein when the organopolysiloxane is applied on a glass plate such that the thickness after application is 0.5 μm and a coating film is washed after immersion in a 2.38 mass % aqueous solution of tetramethylammonium hydroxide (TMAH) for 1 minute, the coating film containing the organopolysiloxane has a solubility in an aqueous alkali solution with a mass loss rate of 90 mass % or more.

10. A high energy beam-curable composition comprising:
(A) a curable branched organopolysiloxane according to any one of claims 1 to 9;
(B) a photoacid generating agent in an amount of 0.1 to 20 parts by mass per 100 parts by mass of the component (A);
(C) a crosslinking agent in an amount of 1 to 30 parts by mass per 100 parts by mass of the component (A); and
(D) an organic solvent.

11. The high energy beam-curable composition according to claim 10, wherein the amount of the crosslinking agent (C) is 5 to 30 parts by mass with respect to 100 parts by mass of the component (A).

12. An insulative coating agent, comprising a high energy beam-curable composition according to claim 10.

13. A resist material, comprising a high energy beam-curable composition according to claim 10.

14. A cured product of a high energy beam-curable composition according to claim 10.

15. A method of using a cured product of a high energy beam-curable composition according to claim 10 as an insulative coating layer.

16. A display device comprising: a layer containing a cured product of a high energy beam-curable composition according to claim 10.
